(19) United States
(12) Patent Application Publication
(10) Pub. No.: US 2019/0341948 A1
(43) Pub. Date: Nov. 7, 2019

(54) ASCERTAINING AN OPERATING POINT OF A NON-LINEAR POWER AMPLIFIER

(71) Applicant: UNIVERSITÄT DER BUNDESWEHR MÜNCHEN, Neubiberg (DE)

(72) Inventors: Andreas Knopp, Bad Elster (DE); Matthias Schraml, Thumsenreuth (DE); Robert Schwarz, Haar (DE); Christian Hofmann, Muenchen (DE)

(21) Appl. No.: 16/462,267

(22) PCT Filed: Oct. 24, 2017
(86) PCT No.: PCT/EP2017/077160

§ 371 Date: May 20, 2019

(30) Foreign Application Priority Data
Nov. 21, 2016 (DE) 10 2016 122 354.9

(51) Int. Cl. H04B 1/04; H03F 3/21; H03F 1/32

(52) U.S. Cl. CPC H04B 1/0475; H03F 3/21; H03F 2200/451; H04B 2001/0425; H03F 1/32

(57) ABSTRACT

Disclosed are a process and a system for ascertaining an operating point of a nonlinear power amplifier, wherein a signal amplified by the power amplifier is received, and a value of a measure of a deviation of the amplitude distribution of the received signal from a Gaussian distribution is ascertained.

### FIELD OF THE INVENTION

The present invention relates to ascertaining the operating point of a power amplifier which is operated at least temporarily in a non-linear gain region. In particular, the present invention relates to ascertaining the operating point of a non-linear high power amplifier using a statistical evaluation of a multi-carrier signal amplified by the high power amplifier.

### BACKGROUND

When power amplifiers are operated in (highly) non-linear gain regions this can give rise to signal distortions, which have a significant adverse effect on the signal quality. For example, in the amplification of a multi-carrier signal by a power amplifier operated in a highly non-linear gain region, non-negligible intermodulation products can be produced.

In order to prevent signal distortions which significantly degrade the signal quality, it is therefore often desirable to maintain the operating point of a power amplifier below a certain threshold or not to operate the power amplifier in too highly non-linear gain ranges. In this context, known methods and devices from the prior art are often complicated to implement, however, and/or only provide inadequate prevention of signal distortions that significantly affect the signal quality.

### SUMMARY

The object of the present invention therefore is to provide a method and a system which allow an operating point of a power amplifier operated at least temporarily in a non-linear gain region to be ascertained and, in particular, the mean input power of the power amplifier to be adjusted on the basis of the ascertained value.

The present invention achieves this object by providing a method and a system for determining an operating point of a non-linear power amplifier.

The present invention is based, in particular, on the fact that signal distortions that result from different operating points of a power amplifier operated at least temporarily in a non-linear gain region differ (measurably) in terms of the amplitude distribution of the distorted signals. Therefore, if a Gaussian noise component additively applied to the distorted signals by a transmission line is separated from the distorted signals, the amplitude distributions of the distorted signals can be used to deduce a respective degree of distortion. On this basis, for example, the operating point of the power amplifier can be adjusted so that signal distortions that significantly affect the signal quality can be prevented, without needing to greatly reduce the output power of the power amplifier unnecessarily.

A method according to the invention comprises ascertaining a value of a measure of a deviation of an amplitude distribution of a signal amplified by a power amplifier, operated at least temporarily in a non-linear gain region, from a Gaussian distribution and controlling at least part of a communication process based on the signal depending on the ascertained value.

Here, the term “power amplifier”, as it is used in the description and the claims, is understood in particular to mean an electronic device that provides an output power which can be controlled via a smaller input power. The relationship between the input and output power in the gain region (for nominal operation) can be typically described by a gain characteristic which assigns a greater output power to each input power. The power gain typically decreases with increasing input power as a saturation range of the power amplifier is approached, which results in a non-linear gain region.

In addition, the term “amplitude distribution”, as it is used in the description and the claims, is understood, in particular, to mean a distribution of amplitude values of the signal sampled over a predefined time interval, i.e. a distribution of a predefined number of sampled amplitude values. In addition, the term “communication process”, as it is used in the description and the claims, is understood, in particular, to mean a process for transmitting signals between communication devices, which typically includes the interpretation of the transmitted signals and thus the generation of digital data on the basis of the transmitted signals.

Because the value of a measure of the deviation of the amplitude distribution of a Gaussian distribution is ascertained, the value ascertained reflects the signal distortion caused by the power amplifier, but is independent of Gaussian-distributed interference sources which corrupt the amplified signal during its transmission along a transmission line. The separation of the effects of interference (that distort the amplified signal during transmission along the transmission line) enables the signal distortion caused by the power amplifier to be determined independently of the transmission line.

Preferably, the method also comprises the adjustment of a mean input power of the power amplifier on the basis of the ascertained value.

This allows the power amplifier to operate continuously in a gain region which enables an appreciable output power to be obtained while maintaining an acceptable level of distortion. The invention is not limited in this respect, however, as a plurality of other uses in terms of the ascertained value are possible, for example checking the technical condition of the power amplifier and controlling the communication process on this basis, monitoring ageing processes in the power amplifier for correction and optimization of link quotas and connection charges, the detection of unwanted interference sources which are coupled into the power amplifier and, for example a (temporary) diversion of communication flows based thereon, etc.

The signal amplified by the power amplifier is preferably a signal transmitted via an interference-prone transmission line and, in particular, a radio signal.

This avoids the need to estimate or measure sources of interference that distort the amplified signal.

Preferably the signal amplified by the power amplifier is a multi-carrier signal or a high-valency modulated single-carrier signal.

The term “multi-carrier signal”, as it is used in the description and the claims, is understood in particular to mean a composite signal formed from a plurality of partial signals of different carrier frequencies or different carrier frequency ranges. In addition, the term “high-valency modulated single carrier signal”, as it is used in the description and claims, is understood in particular to mean a single carrier signal with at least 8, at least 16 or at least 32 constellation points.

In a power amplifier which amplifies a multi-carrier signal, it is possible, for example, by adjusting the mean input power of the power amplifier, to prevent the creation of intermodulation products or reduce them to a level which is not detrimental to the required transmission quality.

Preferably, a linearity of the power gain of the power amplifier decreases with increasing input power of the power amplifier and the adjustment of the mean input power of the power amplifier based on the ascertained value comprises reducing the mean input power of the power amplifier based on the ascertained value.

As a result, a distortion which significantly degrades the signal quality due to the operation of the power amplifier with an excessively high mean input power can be detected and/or avoided, as the amplification window can be limited to a gain region in which a deviation from a linear power gain does not exceed a predetermined value.

In this context, it should be noted that an increase in the operating point in the direction of saturation enables a higher output power of the power amplifier and thereby a higher received power. If, however, distortion effects in the signal reduce the signal-to-noise ratio (SNR) by a greater amount than the increase in received power increases it, then the previous measure brings no advantages. Thus, it is advantageous to operate the power amplifier at an optimum point with respect to the signal-to-noise ratio of the received signal. In addition, a design of the amplifier without capacity reserves is only possible if the operating point of the amplifier is known. If, on the other hand, this is not known, then safety margins need to be allowed for.

The adjustment of the mean input power of the power amplifier on the basis of the ascertained value preferably comprises a comparison of the ascertained value with one or more predetermined values.

The predetermined values can be ascertained both by measurement and by calculation or simulation. In particular, a threshold value can be determined either by measurement or calculation, which triggers an adjustment of the mean power input when exceeded or undershot.

The measure of the deviation of the amplitude distribution is preferably based on cumulants whose order is greater than 2 and is even.

Cumulants of order greater than 2 are unaffected by a Gaussian-distributed interference of the amplified signal. In addition, even-order cumulants are also non-zero for amplitude distributions that are symmetric around zero.

The measure of deviation of the amplitude distribution preferably depends linearly on a ratio of a power of a cumulant of a first even order to a power of a cumulant of a second even order, wherein the power of the first cumulant times the order of the first cumulant is equal to the power of the second cumulant times the order of the second cumulant.

As a result, the respective attenuation factors completely cancel each other out, which means that the ratio is attenuation-independent.

The measure of the deviation of the amplitude distribution preferably has a linear dependence on a ratio of a cumulant of first even order to the square of a cumulant of a second even order, wherein the first even order is equal to twice the second even order.

The dependence of the ascertained value on the attenuation of the amplified signal along the transmission line is thereby avoided and in addition, a linear dependence between the ascertained value and the operating point can be achieved.

Preferably, the first even order is 8 and the second even order is 4.

This means that cumulants of very low order can be used, which simplifies the determination of the cumulant used and reduces the effort required for the application of the method.

A system according to the invention for ascertaining an operating point of a non-linear power amplifier comprises a receiving unit configured for receiving a signal amplified by the power amplifier, and a calculation unit configured for determining a value of a measure of a deviation of an amplitude distribution of the received signal from a Gaussian distribution.

The term “non-linear power amplifier”, as it is used in the description and claims, refers in particular to a power amplifier, the gain characteristic of which is non-linear at least in some sections of a nominal gain region of the power amplifier.

In addition, the term “calculation unit”, as it is used in the description and claims, is intended to refer in particular to a unit provided with a processor, such as a microcontroller, a digital signal processor or a Field Programmable Gate Array.

The system preferably comprises the power amplifier, wherein the system is configured to control a mean input power of the power amplifier on the basis of the ascertained value.

This allows an operation of the power amplifier in a too highly non-linear gain region to be avoided.

### BRIEF DESCRIPTION OF THE DRAWINGS

The invention is described below in the detailed description on the basis of exemplary embodiments, with reference to the drawings which show:

FIG. 1 a schematic view of an embodiment of the system according to the invention;

FIG. 2 a schematic view of a first device, which can contain parts of the system according to the invention;

FIG. 3 a schematic view of a second device, which can contain parts of the system according to the invention;

FIG. 4 a schematic view of a third device, which can contain parts of the system according to the invention;

FIG. 5 a flow diagram of the method according to the invention;

FIG. 6 a curve of an output backoff (OBO) against a measure of a deviation of an amplitude distribution of a signal amplified by the power amplifier from a Gaussian distribution for various signals generated by means of a Monte-Carlo simulation;

FIG. 7 shows a curve of the output backoff against a measure of a deviation of an amplitude distribution of a signal amplified by the power amplifier from a Gaussian distribution, which are based on random data sequences generated by means of simulation; and

FIG. 8 a curve of the mean squared error of an operating point estimate for different operating point values against the number of amplitude values used for the estimate.

In the drawings, equivalent elements are labelled with identical reference numerals.

### DETAILED DESCRIPTION

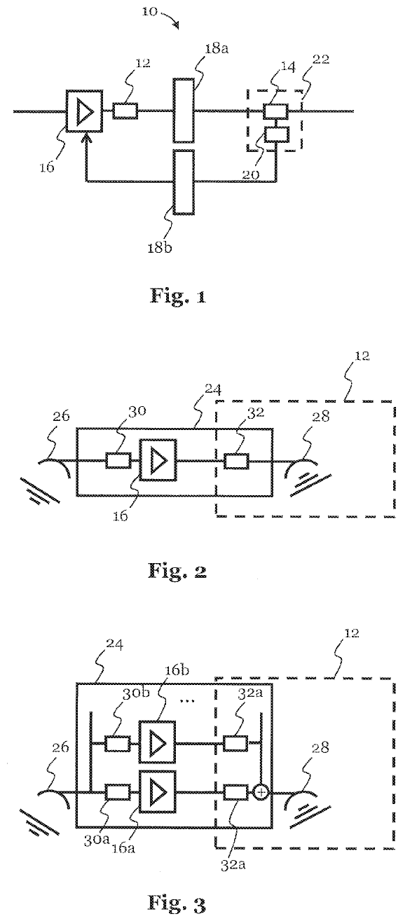

FIG. 1 shows a schematic elevation of a communication system 10. The communication system 10 comprises a transmitting unit 12 and a receiving unit 14. The transmitting unit 12 transmits a signal amplified by a power amplifier 16 (for example, a travelling wave tube) over a first transmission line 18a to the receiving unit 14. The receiving unit 14 provides the received signal or parts of the received signal (e.g. sampled signal amplitude values Sᵢ) to a calculation unit 20. Receiving unit 14 and calculation unit 20 can form a system 22 for ascertaining the operating point of the power amplifier 16, wherein, as indicated in FIG. 1 by an arrow, the mean input power of the power amplifier 16 can be adjusted or controlled on the basis of the ascertained operating point.

Transmitting unit 12 and power amplifier 16, as shown in FIG. 2, can be arranged in a device 24, such as a satellite or an airborne communication platform. The device 24 can comprise a receiving antenna 26 and a transmitting antenna 28. A (multiple-carrier) signal received by the receiving antenna 26 can be forwarded via a first filter 30, such as a first bandpass filter or an “input multiplexer” connected to the receiving antenna 26, to the power amplifier 16. In addition, the (multi-carrier) signal amplified by the power amplifier 16 can be forwarded via a second filter 32 connected to the power amplifier 16, such as a second bandpass filter 32 or an “output multiplexer”, to the transmitting antenna 28.

The transmitting antenna 28 can transmit the amplified and (optionally) bandpass filtered signal to the receiving unit 14, which can comprise a filter, such as a bandpass filter, a linear power amplifier and a receiving antenna, or can be connected via a filter, such as a bandpass filter (not shown) and a linear power amplifier (not shown) to a receiving antenna (not shown). The device 24 can also comprise a control unit (not shown) for adjusting or controlling the mean input power of the power amplifier 16, which is configured to receive control data (e.g. from the system 22) via the receiving antenna 26, and to adjust or control the mean input power of the power amplifier 16 on the basis of the control data.

As shown in FIG. 3, the device 24 can comprise a plurality of power amplifiers 16a, 16b, etc. and, optionally, a plurality of first filters 30a, 30b, etc. (e.g. first bandpass filters) and second filters 32a, 32b, etc. (e.g. second bandpass filters), wherein a multi-carrier signal received by the receiving antenna 26 is split by the first filters 30a, 30b, etc. and can be amplified by the power amplifiers 16a, 10, etc. The enhanced signals can be (optionally) filtered by the second filters 32a, 32b, etc., summed using an adder and transmitted as an amplified multi-carrier signal via the transmitting antenna 28 to the receiving unit 14.

Furthermore, between the first filters 30a, 30b, etc. and the power amplifiers 16a, 16b, etc. another input network (not shown) can be provided. The input network can comprise a plurality of signal splitters and signal combiners, so that a wide range of partial signals and partial signal combinations of the multi-carrier signal (possibly with different weighting factors) can be distributed to the power amplifiers 16a, 16b, etc. Between the power amplifiers 16a, 16b, etc. and the second filters 32a, 32b, etc., an output network (not shown) inverse to the input network can also be provided, in which the partial signals or partial signal combinations amplified by the power amplifiers 16a, 16b, etc. can be added together again. The input network, power amplifier 16a, 16b, etc. and output network can be designed e.g. as multi-port amplifiers (MPA).

Also, as shown in FIG. 4, a signal processing unit 34a is provided between the first filter 30a and the power amplifier 16a, which interprets the filtered analogue signal (e.g. as a Phase Shift Keying (PSK) signal, an Amplitude Shift Keying (ASK) signal, a quadrature amplitude modulation (QAM) signal, such as a 4-QAM signal, a 16-QAM signal, a 64-QAM signal, a 256-QAM signal, etc., or an Amplitude Shift Keying Phase modulation (APSK) signal) and converts it into corresponding digital data). Optionally, the signal processing unit 34a can be configured to carry out a forward error correction. From the digital data, the signal processing unit 34a (by means of phase shift keying, PSK, amplitude shift keying, ASK, quadrature amplitude modulation, QAM, or amplitude shift keying phase modulation APSK) can generate an analogue signal which is forwarded to the power amplifier 16a. As shown in FIG. 4, the power amplifiers 16b, etc. can also be connected downstream of corresponding signal-processing units 34b, etc., which similarly to the signal processing unit 34a described, interference-suppress or “clean up” the respective analogue signal.

The signal processing unit 34a can be additionally configured to adjust or control a mean power input of the power amplifier 16a or of all the power amplifiers 16a, 16b, etc. on the basis of the received signal. Likewise, each signal processing unit 34a, 34b, etc. can be configured to adjust or control a mean input power of the power amplifier 16a, 16b, etc. connected to the respective signal processing unit 34a, 34b, etc. on the basis of the received signal. Moreover, as explained in conjunction with FIG. 2, a control unit (not shown) can be provided which receives data from one of the signal processing units 34a, 34b, etc. or from an additional signal processing unit (not shown), and adjusts or controls the mean input power of one or all of the power amplifiers 16a, 16b, etc on the basis of the received data.

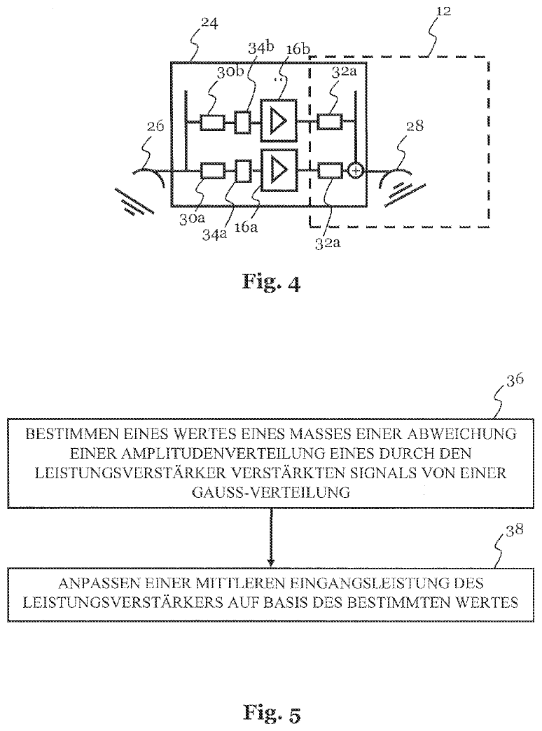

The signal received, on the basis of which the mean input power of the power amplifier 16 or one or all of the power amplifiers 16a, 16b, etc. is adjusted or controlled, can be based, as mentioned in connection with FIG. 1, on the operating point of the power amplifier 16 ascertained or on the operating point(s) ascertained of one or all of the power amplifiers 16a, 16b, etc. To this end the calculation unit 20 shown in FIG. 1, as shown in step 36 of the flow diagram in FIG. 5, can be configured to determine a value of a measure of a deviation from a Gaussian distribution of an amplitude distribution of an (optionally) (bandpass-)filtered signal, which is provided to the calculation unit 20 by the receiving unit 14. For example, the calculation unit 20 can be configured to estimate a value of a cumulant of even order greater than 2 with regard to the signal provided. For example, the calculation unit 20 can be configured to estimate one or more estimated values with regard to one or more of the cumulants:

fourth order \hat{K}₄=\hat{μ}₄−3(\hat{μ}₂)²,

sixth order \hat{K}₆=\hat{μ}₆−15\hat{μ}₄\hat{μ}₂−10(\hat{μ}₃)²+30(\hat{μ}₂)³,

eighth order \hat{K}₈=\hat{μ}₈−28\hat{μ}₆\hat{μ}₂−35(\hat{μ}₄)²+420\hat{μ}₄(\hat{μ}₂)²−630(\hat{μ}₂)⁴,
etc.,
   on the basis of a plurality of discrete signal amplitude values Sᵢ of the signal provided with \hat{μ}ₐ=Σᵢ₌₁^{N}Sᵢ^{a} (under the assumption that the mean value of the discrete signal amplitude values Sᵢ is equal to zero).

In addition, the calculation unit 20 can be configured with regard to the signal provided to estimate a value of a quotient of a cumulant of first even order greater than 2 and the square of a cumulant of second even order greater than 2, wherein the first order is equal to twice the value of the second order. This allows a value to be determined which is independent of a (linear) signal attenuation along the first transmission line 18a (and of the optional linear signal gain in the system 22). For example, the calculation unit 20 determines an estimated value of the ratio of the eighth-order cumulant and the square of the fourth-order cumulant

$${\hat{Q}}_{8 , 4} = \frac{{\hat{κ}}_{8}}{{( {\hat{κ}}_{4} )}^{2}} .$$

As a result the above condition is satisfied using the smallest possible cumulants, which allows the complexity in determining the value by the calculation unit 20 to be kept low. However, it goes without saying that estimated values based on other cumulant quotients are also possible, in which a value independent of the signal attenuation is ascertained. In particular, by choosing the dividend and divisor, as shown in the previous example, in such a way that the respective attenuation factors completely cancel each other out (i.e. could be omitted), which means the ratio is independent of the attenuation. This can be achieved, in particular, by the product of order and exponent being equal in both dividend and divisor.

As shown in step 38 of the flow diagram in FIG. 5, the ascertained value can be used to adjust or control a mean input power of the power amplifier 16, or of one or all of the power amplifiers 16a, 16b, etc. In addition, the calculation unit 20 can be configured, for example, to store a threshold value with regard to the operating point of the power amplifier 16 or of one or all of the power amplifiers 16a, 16b, etc., which corresponds to a desired output backoff or desired output backoffs. If this threshold value is exceeded, the calculation unit 20 can be configured to signal that the mean input power of the power amplifier 16 or the mean input power of one or all of the power amplifiers 16a, 16b, etc. should be reduced.

Conversely, if the threshold is not reached, the calculation unit 20 can be configured to signal that the mean input power of the power amplifier 16 or the mean input power of one or all power amplifiers 16a, 16b, etc. can be increased. For this purpose, the calculation unit 20, as shown in FIG. 1, can transmit a signal which indicates a reduction or a possible increase in a mean input power over the second transmission line 18b to the power amplifier 16 or the receiving antenna 26. In this context it should be noted that, particularly in the case of a bidirectional communication between the transmitting unit 12 and the receiving unit 14, the first transmission line 18a and the second transmission line 18b can be the same.

Furthermore, from the ascertained value an operating point of the power amplifier 16 and/or the operating point(s) of one or all power amplifiers 16a, 16b, etc. can be ascertained. To this end, for example, the ascertained value can be compared with tabulated values and if a match exists, an output backoff or output backoffs associated with the matching value (within the accuracy of the process) can be ascertained as an operating point of the power amplifier 16 or as operating point(s) of one or all power amplifiers 16a, 16b, etc. The threshold value and the tabulated values can be determined, for example, by means of one or more measurements, by analysing for various known output backoffs of the power amplifier 16, or of one or all of the power amplifiers 16a, 16b, etc., a signal amplified by the power amplifier 16 or by one or all of the power amplifiers 16a, 16b, etc., as described above, by estimating one or more cumulants and the values determined by the analysis being assigned to the respective output backoffs.

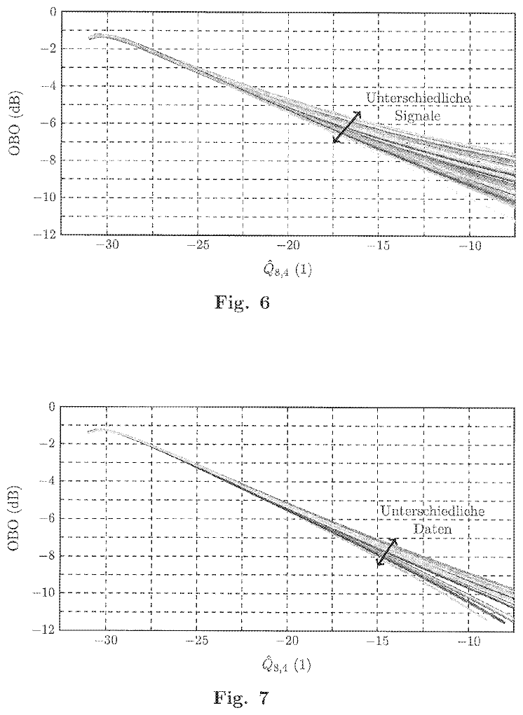

The threshold value and the tabulated values can be calculated based on a model of the 3o communication system 10 (and in particular the gain curve of the power amplifier 16 or the gain curve(s) of one or all power amplifiers 16a, 16b, etc.). To this end, FIG. 6 shows a relationship between output backoff (OBO) and

$${\hat{Q}}_{8 , 4} = \frac{{\hat{κ}}_{8}}{{( {\hat{κ}}_{4} )}^{2}} ,$$

calculated based on a model of the communication system 10, for different multi-carrier signals, generated by means of a Monte Carlo simulation and amplified in accordance with a non-linear gain curve comprising 15≤L≤40 carriers, at a sampling rate of 40 MHz and K=20,000 sample values.

As shown in FIG. 6, the values for \hat{Q}_{8,4} converge for larger output backoffs (OBOs). This shows by example that, in the absence of information about the signal received by the receiving unit 14, a “blind estimate” of the threshold value and the (relevant) tabulated values for correspondingly large output backoffs (OBO) is possible with sufficient accuracy. In addition, by the use of a larger number of sample values and a plurality of series of sampling values statistically independent of each other, the accuracy of the curve shown in FIG. 6 can be further improved. To illustrate this, FIG. 8 shows the mean squared error of the OBO estimate for different values of \hat{Q}_{8,4} plotted against the number of sample values used for the estimate.

If additional information about the signal is available then this can be used to calculate the relationship between output backoff (OBO) and

$${\hat{Q}}_{8 , 4} = \frac{{\hat{κ}}_{8}}{{( {\hat{κ}}_{4} )}^{2}}$$

in situations in which the above “blind estimation” does not deliver sufficiently accurate values. If the signal S′ to be amplified can be described, for example, by

$${S}^{′} = {\sum }_{l = 1}^{L} Re \{ {A}_{l} {\sum }_{n = - ∞}^{∞} {d}_{l}^{′} ( n ) {h}_{l} ( kT - {nT}_{S l} ) {e}^{j 2 π ( {f}_{0} + Δ {f}_{l} ) kT} \}$$

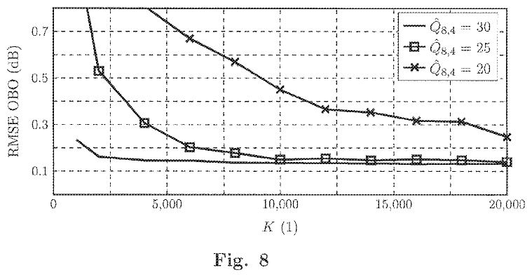

with a random data sequence d′ₗ, a known amplitude Aₗ, a known pulse shaping filter hₗ, a known symbol time T_{Sl} and a known sampling period T, the relationship shown in FIG. 7 between output backoff (OBO) and

$${\hat{Q}}_{8 , 4} = \frac{{\hat{κ}}_{8}}{{( {\hat{κ}}_{4} )}^{2}}$$

can be calculated by simulation of different random data sequences d′ₗ.

If such information about the signal is not or only partially available, signal parameters can also be obtained by means of a signal analysis. For example, the carrier frequencies, bandwidths and relative signal powers of all carriers of a signal received by the receiving unit 14 can be determined. In addition, the modulation format can be determined, for example, using a cumulant-based method such as in W. Su & J. A. Kosinski, “Higher Order Blind Signal Feature Separation: An Enabling technology For Battlefield Awareness”, U.S. Army CERDEC, Tech. Rep., 2006. The amplified signal can then be simulated in accordance with the information determined and the relationship between output backoff (OBO) and

$${\hat{Q}}_{8 , 4} = \frac{{\hat{κ}}_{8}}{{( {\hat{κ}}_{4} )}^{2}}$$

can be calculated.

### LIST OF REFERENCE NUMERALS

10 communication system
12 transmitting unit
14 receiving unit
16, 16a, 16b power amplifier
18a, 18b transmission line
20 calculation unit
22 system
24 device
26 receiving antenna
28 transmitting antenna
30, 30a, 30b filter
32, 32a, 32b filter
34a, 34b signal processing unit
36 process step
38 process step

1-12. (canceled)

13. A method, comprising:
ascertaining a value of a measure of a deviation of an amplitude distribution of a signal, amplified by a power amplifier operated at least temporarily in a non-linear gain region, from a Gaussian distribution; and
controlling at least part of a communication process based on the signal depending on the ascertained value.

14. The method according to claim 13, further comprising:
adjusting a mean power input of the power amplifier on the basis of the ascertained value.

15. The method according to claim 13, wherein the signal amplified by the power amplifier is a signal transmitted over an interference-prone transmission line.

16. The method according to claim 13, wherein the signal amplified by the power amplifier is one of a multi-carrier signal and a high-valency modulated single-carrier signal.

17. The method according to claim 14, wherein the signal amplified by the power amplifier is one of a multi-carrier signal and a high-valency modulated single-carrier signal.

18. The method according to claim 13, wherein a linearity of the power gain of the power amplifier decreases with increasing input power of the power amplifier and the adjustment of the mean input power of the power amplifier on the basis of the ascertained value comprises a reduction of the mean input power of the power amplifier on the basis of the ascertained value.

19. The method according to claim 14, wherein a linearity of the power gain of the power amplifier decreases with increasing input power of the power amplifier and the adjustment of the mean input power of the power amplifier on the basis of the ascertained value comprises a reduction of the mean input power of the power amplifier on the basis of the ascertained value.

20. The method according to claim 14, wherein the adjustment of the mean input power of the power amplifier on the basis of the ascertained value comprises a comparison of the ascertained value with one or more predetermined values.

21. The method according to claim 18, wherein the adjustment of the mean input power of the power amplifier on the basis of the ascertained value comprises a comparison of the ascertained value with one or more predetermined values.

22. The method according to claim 13, wherein the measure of the deviation of the amplitude distribution is based on cumulants whose order is greater than 2 and is even.

23. The method according to claim 22, wherein the measure of the deviation of the amplitude distribution depends on a ratio of a power of a cumulant of a first even order to a power of a cumulant of a second even order, wherein the power of the first cumulant times the order of the first cumulant is equal to the power of the second cumulant times the order of the second cumulant.

24. The method according to claim 22, wherein the measure of the deviation of the amplitude distribution depends linearly on a ratio of a cumulant of first even order to a square of a cumulant of a second even order, wherein the first even order is equal to twice the second even order.

25. The method according to claim 23, wherein the measure of the deviation of the amplitude distribution depends linearly on a ratio of a cumulant of first even order to a square of a cumulant of a second even order, wherein the first even order is equal to twice the second even order.

26. The method according to claim 24, wherein the first even order is 8 and the second even order is 4.

27. A system for ascertaining an operating point of a non-linear power amplifier, comprising:
a receiving unit, configured for receiving a signal amplified by the power amplifier; and
a calculation unit, configured to ascertain a value of a measure of a deviation of an amplitude distribution of the received signal from a Gaussian distribution.

28. The system as claimed in claim 27,
further comprising the power amplifier, wherein the system is configured to control a mean input power of the power amplifier on the basis of the ascertained value.

29. The method according to claim 13, wherein said signal is a radio signal.

30. A method, comprising:
ascertaining a value of a measure of a deviation of an amplitude distribution of a signal, amplified by a power amplifier operated at least temporarily in a non-linear gain region, from a Gaussian distribution; and
controlling at least part of a communication process based on the signal depending on the ascertained value,
wherein the measure of the deviation of the amplitude distribution is based on cumulants whose order is greater than 2 and is even,
wherein the measure of deviation of the amplitude distribution depends on a ratio of a power of a cumulant of a first even order to a power of a cumulant of a second even order, wherein the power of the first cumulant times the order of the first cumulant is equal to the power of the second cumulant times the order of the second cumulant.

31. The system of claim 27, wherein the measure of the deviation of the amplitude distribution is based on cumulants whose order is greater than 2 and is even.

32. The system of claim 31, wherein the measure of deviation of the amplitude distribution depends on a ratio of a power of a cumulant of a first even order to a power of a cumulant of a second even order, wherein the power of the first cumulant times the order of the first cumulant is equal to the power of the second cumulant times the order of the second cumulant.
